(19) United States
(12) Patent Application Publication
(10) Pub. No.: US 2018/0286857 A1
(43) Pub. Date: Oct. 4, 2018

(54) SEMICONDUCTOR DEVICE WITH SNUBBER AND ASSOCIATED FABRICATION METHOD

(71) Applicant: Chengdu Monolithic Power Systems Co., Ltd., Chengdu (CN)

(72) Inventors: Huaifeng Wang, Chengdu (CN); Eric Braun, Mountain View, CA (US); Ling Wang, Chengdu (CN)

(21) Appl. No.: 15/940,910

(22) Filed: Mar. 29, 2018

(30) Foreign Application Priority Data
Mar. 31, 2017 (CN) 201710211272.X

(51) Int. Cl. H01L 27/06; H01L 29/78; H01L 29/66

(52) U.S. Cl. CPC H01L 27/0629; H01L 29/7825; H01L 29/66734; H01L 29/66704; H01L 29/7813

(57) ABSTRACT

A semiconductor device having a dummy trench structure. The dummy trench structure vertically extends from the top surface of the semiconductor device through a body region into a semiconductor initial layer, and the body region separates the dummy trench structure from a source region. The dummy trench structure has a trench dielectric and a trench conductive material. The semiconductor initial layer, the trench dielectric and the trench conductive material are served as a capacitor of an integrated snubber of the semiconductor device, and the trench conductive material is served as a resistor of the snubber.

### CROSS-REFERENCE TO RELATED APPLICATION(S)

This application claims the benefit of CN application No. 201710211272.X filed on Mar. 31, 2017 and incorporated herein by reference.

### TECHNICAL FIELD

The present invention generally relates to semiconductor devices, and more particularly but not exclusively relates to a semiconductor power transistor having snubbers and associated fabricating processes.

### BACKGROUND

Power transistor has often been used in high power applications, such as switching power supplies, DC-DC switching converters, etc. In a DC-DC switching converter, an input voltage can be converted to an output voltage through controlling power transistors on and off. However, an input capacitor, parasitic inductors of the DC-DC switching converter, and power transistors will constitute resonance loops. The resonance loops will be oscillated resulting in voltage spikes and ringing when power transistors are switched. Thus, snubber may be necessary to have in the DC-DC switching converter for absorbing the voltage spikes and ringing in case of the damages of the power transistors.

FIG. 1 schematically illustrates a prior DC-DC converter 50. The DC-DC converter 50 comprises a high side switch having a plurality of high side MOS cells (HS1, HS2 . . . , HSn), and a low side switch having a plurality of low side MOS cells (LS1, LS2 . . . , LSn), wherein n is an integer larger than or equal to 2. An input voltage signal VIN is converted to an output voltage signal VOUT through controlling the high side switch and the low side switch on and off. Parasitic inductors Lr of the DC-DC converter 50 are also illustrated in FIG. 1. Each high side MOS cell and the corresponding low side MOS cell have a common connection node, respectively illustrated as SW1, SW2, . . . , SWn. When the plurality of low side MOS cells and the plurality of high side MOS cells are switched on and off, voltage spikes and ringing on each of the common connection nodes (SW1, SW2, . . . , SWn) are generated. Therefore, in FIG. 1, a plurality of snubbers each of which includes a resistor Rsn and a capacitor Csn are respectively connected between each common connection nodes and a logic ground to absorb the voltage spikes and reduce the cycles of ringing.

Generally, the snubbers are integrated in a semiconductor device with a power switch. In prior art, for example, oxides and polysilicons are deposited on the top surface of the semiconductor device to form the snubbers. However, the capacitance of the capacitor Csn of the snubbers formed on the top surface of the semiconductor device is limited. The suppression ability of the voltage spikes and ringing of the DC-DC converter is related to the capacitance of the capacitor Csn and the output capacitance Coss of the low side switch. A low capacitance of the capacitor Csn is unfavorable for the suppressions of the voltage spikes and ringing. It is therefore desired to provide a new semiconductor device for resolving some or all of the above deficiencies.

### SUMMARY

In one embodiment, the present invention discloses a main cell region of the Laterally Diffused Metal Oxide Semiconductor (LDMOS) device, comprising: a semiconductor initial layer of a first conductivity type; a drain region of the first conductivity type formed in the semiconductor initial layer; a body region of a second conductivity type opposite to the first conductivity type, formed adjacent to the drain region in the semiconductor initial layer; a gate region, formed on the body region; a source region of the first conductivity type formed in the body region, wherein the source region is at one side of the gate region, and the drain region is at the other side of the gate region; and a first dummy trench structure, vertically extending from the top surface of the LDMOS device through the body region into the semiconductor initial layer, wherein the body region separates the first dummy trench structure from the source region.

In one embodiment, the present invention further discloses a main cell region of a Verticality Diffused Metal Oxide Semiconductor (VDMOS) device, comprising: a semiconductor substrate of a first conductivity type, served as a drain region; an epitaxial layer of the first conductivity type grown on the semiconductor substrate; a body region of a second conductivity type opposite to the first conductivity type formed in the top of the epitaxial layer; a source region of the first conductivity type formed in the body region; a trench gate region, vertically extending from the top surface of the epitaxial layer through the body region into the epitaxial layer; and a first dummy trench structure, vertically extending from the top surface of the epitaxial layer through the body region into the epitaxial layer, wherein the body region separates the first dummy trench structure from the source region.

In one embodiment, the present invention further discloses a method of fabrication a LDMOS device, comprising forming a main cell region, wherein forming the main cell region comprises: forming a semiconductor initial layer of a first conductivity type; forming a first dummy trench structure in the semiconductor initial layer; forming a body region of a second conductivity type opposite to the first conductivity type in the semiconductor initial layer, wherein the first dummy trench structure vertically extends from the top surface of the semiconductor initial layer through the body region into the semiconductor initial layer; forming a gate region on the body region; forming a drain region of the first conductivity type adjacent to the body region in the semiconductor initial layer; and forming a source region of the first conductivity type in the body region, wherein the source region is at one side of the gate region, and the drain region is at the other side of the gate region, and wherein the body region separates the first dummy trench structure from the source region.

In one embodiment, the present invention further discloses a VDMOS device, comprising forming a main cell region, wherein forming the main cell region comprises: providing a semiconductor substrate of a first conductivity type, served as a drain region; forming an epitaxial layer of the first conductivity type on the semiconductor substrate; forming a first dummy trench structure and a trench gate region in the epitaxial layer; forming a body region of a second conductivity type opposite to the first conductivity type in the epitaxial layer, wherein the first dummy trench structure and the trench gate region vertically extend from the top surface of the epitaxial layer through the body region into the epitaxial layer; and forming a source region of the first conductivity type in the body region, wherein the body region separates the first dummy trench structure from the source region

### BRIEF DESCRIPTION OF THE DRAWINGS

Non-limiting and non-exhaustive embodiments are described with reference to the following drawings. The drawings are only for illustration purpose. Usually, the drawings only show part of the system or circuit of the embodiment, and the same reference label in different drawings have the same, similar or corresponding features or functions.

FIG. 1 schematically illustrates a prior DC-DC converter 50.

FIG. 2 illustrates a cross-sectional view of a LDMOS device 100 according to an embodiment of the present invention.

FIG. 3 illustrates simulation waveforms of the prior DC-DC converter 50.

FIG. 4 schematically illustrates a prior DC-DC converter 300 having a plurality of snubbers connected between the node SW1 and the logic ground.

FIG. 5 illustrates a cross-sectional view of a LDMOS device 400 according to an embodiment of the present invention.

FIGS. 6-10 illustrate cross-sectional views illustrating a method of fabricating the LDMOS device 400 according to an embodiment of the present invention.

FIG. 11 illustrates a cross-sectional view of a VDMOS device 500 according to an embodiment of the present invention.

FIG. 12 illustrates a cross-sectional view of a VDMOS device 600 according to an embodiment of the present invention.

FIGS. 13-15 illustrate cross-sectional views illustrating a method of fabricating the VDMOS device 600 according to an embodiment of the present invention.

The use of the same reference label in different drawings indicates the same or like components.

### DETAILED DESCRIPTION

The embodiments of the present invention are described in the next. While the invention will be described in conjunction with various embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the embodiments of the present invention, numerous specific details are set forth in order to provide a thorough understanding of the embodiments of the present invention. However, it will be obvious to one of ordinary skill in the art that without these specific details the embodiments of the present invention may be practiced. And it should be noted that well-know circuits, materials, and methods are not described in detail so as not to unnecessarily obscure aspect of the embodiments of the present invention.

In the specification and appended claims, “on”, “in”, “into” “onto”, “below”, “on the top of”, “in the front of”, “right”, “left” and/or the like terms may be employed to describe relative positions of related elements, but not to add absolute restrictions to the elements. For example, when one layer is described “on” the other layer, it means one layer may be located on the other one directly, or additional layers may exist between them. Though “region” or “regions”, “trench” or “trenches”, “pad” or “pads” and other similar terms are referred to in the description with singular or plural forms, it is not confined to the singular or plural numbers, and any number is considered in the embodiments. The semiconductor device may comprise a field effect transistor, a bipolar junction transistor and/or other similar devices, thus, the “gate/gate region”, “source/source region”, and “drain/drain region” may comprise “base/base region”, “emitter/emitter region”, and “collector/collector region” respectively, and may further comprise structures similar as the “gate/gate region”, “source/source region”, and “drain/drain region”.

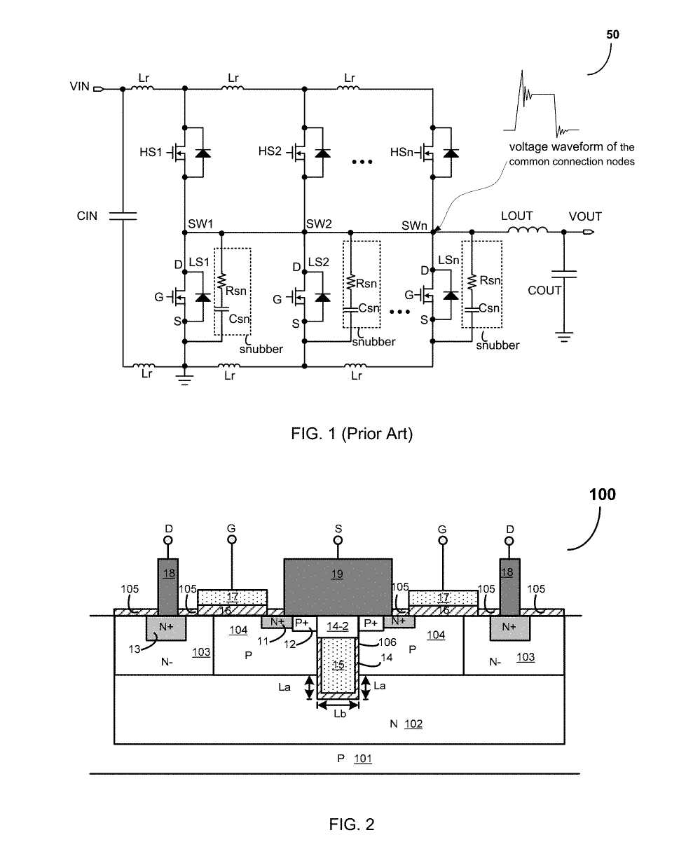

FIG. 2 illustrates a cross-sectional view of a Laterally Diffused Metal Oxide Semiconductor (LDMOS) device 100 according to an embodiment of the present invention. The LDMOS device 100 may comprise a semiconductor initial layer 102 of a first conductivity type, a source region 11 of the first conductivity type, a drain region 13 of the first conductivity type, a gate region, a drift region 103 of a light doped first conductivity type and a body region 104 of a second conductivity type opposite to the first conductivity type. In an embodiment, the semiconductor initial layer 102 may comprise a well region of the first conductivity type formed in a semiconductor substrate. In another embodiment, the semiconductor initial layer 102 may comprise an epitaxial layer of the first conductivity type grown on the semiconductor substrate. In the exemplary embodiment of FIG. 2, the semiconductor initial layer 102 is illustrated to be a well region of the first conductivity type formed in the semiconductor substrate of the second conductivity type. In the following description, the first conductivity type is assumed to be N-type conductivity, and the second conductivity type is assumed to be P-type conductivity. However, one with ordinary skills in the art should note that in other embodiments, the N-type conductivity and the P-type conductivity may also be applied alternatively for the first conductivity type and the second conductivity type.

In detail, the P-type body region 104 is formed in the top of the N-type well region 102, and the light doped N− drift region 103 is formed adjacent to the P-type body region 104. A heavy doped P+ body contact region 12 and the N-type source region 11 is formed in the P-type body region 104. The N-type drain region 13 is formed in the light doped N− drift region 103. A drain metal contact 18 served as a drain electrode D contacting the N-type drain region 13 through vias is formed on the N-type drain region 13, and electrically connected to outside of the LDMOS device 100. A source metal contact 19 served as a source electrode S contacting the N-type source region 11 and the P+ body contact region 12 through vias is formed on the top surface of the P-type body region 104, and electrically connected to outside of the LDMOS device 100. The gate region is formed on the P-type body region 104. The N-type drain region 13 is at one side of the gate region, and the N-type source region 11 is at the other side of the gate region. The gate region comprises a gate dielectric layer 16, and a gate conductive layer 17 (e.g., polysilicon) formed on the gate dielectric layer 16. The gate conductive layer 17 is electrically connected to outside of the LDMOS device 100 through a gate metal contact that serves as a gate electrode G. An interlayer dielectric layer (IDL) 105 is then formed onto the top surface of the N-type well region 102 to insulate the N-type drain region 13 from the N-type source region 11. It should be noted that the materials, conductivities and the dopants mentioned above can be changed in accordance with the different applications.

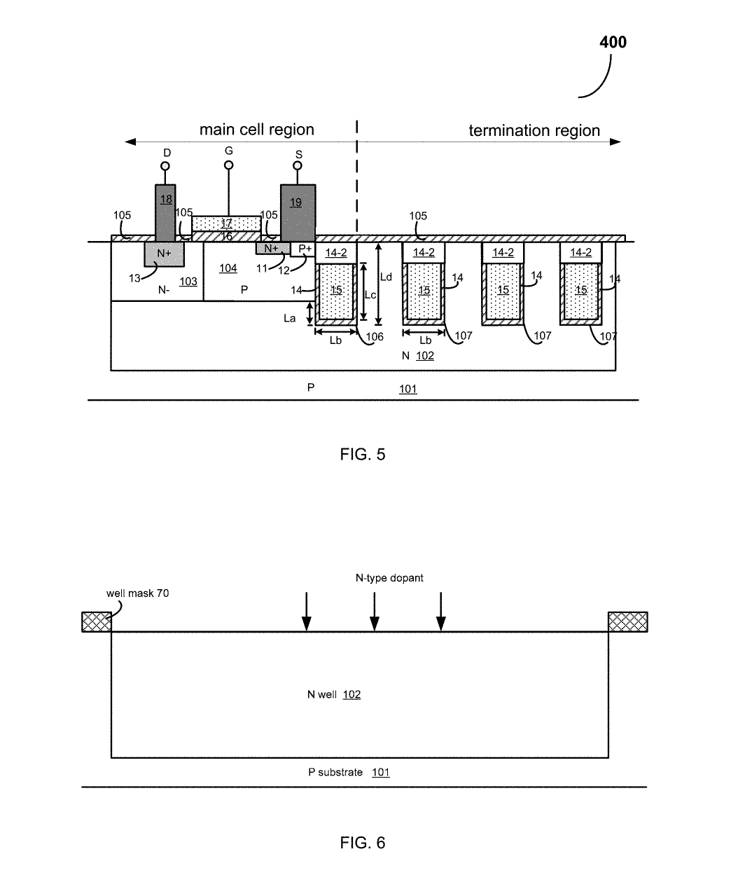

In the exemplary embodiment of FIG. 2, the LDMOS device 100 further comprises a dummy trench structure 106. The dummy trench structure 106 vertically extends from the top surface of the LDMOS device 100 through the P-type body region 104 into the N-type well region 102. The P-type body region 104 separates the dummy trench structure 106 from the N-type source region 11. The dummy trench structure 106 comprises a dummy trench, a first trench dielectric 14 and a trench conductive material 15. The depth of the dummy trench is larger than the depth of the P-type body region 104. As shown in the FIG. 2, the depth difference of the depth of the dummy trench and the depth of the P-type body region 104 is labeled as La, and the width of the trench is labeled as Lb. The first trench dielectric 14 is formed on the bottom and sidewalls of the dummy trench. The trench conductive material 15 is then filled on the first trench dielectric 14 in the dummy trench. In accordance with the different semiconductor fabrication processes of the LDMOS device 100, the filling height of the trench conductive material 15 is different. For example, in an ion-implantations process adopting mask, the dummy trench can be completely filled with the trench conductive material 15, and the IDL 105 is adopted to insulate the trench conductive material 15 from the source metal contact 19. In another embodiment, for example, in an ion-implantations process adopting gate self-aligned, the filling height Lc (illustrated in FIG. 5) of the trench conductive material 15 is smaller than the height Ld (illustrated in FIG. 5) of the dummy trench (Lc<Ld), and the top surface of the trench conductive material 15 is lower than the top surface of the of the dummy trench, and a second trench dielectric 14-2 needs to be formed on the trench conductive material 15 and the dummy trench is completely filled after the second trench dielectric 14-2 is formed. In an embodiment, the top surface of the filling trench conductive material 15 is lower than the bottom surface of the N-type source region 11. In such an application, the first trench dielectric 14 vertically insulates the trench conductive material 15 from the P-type body region 104 and the N-type well region 102, and laterally insulates the trench conductive material 15 from the N-type well region 102. The second trench dielectric 14-2 insulates the trench conductive material 15 from the source metal contact 19. In an embodiment, the first trench dielectric 14 and the gate dielectric layer 16 may be formed in the same process step adopting the same dielectric materials such as silicon dioxide, while the second trench dielectric 14-2 may be formed in another process step adopting different dielectric material such as silicon nitride. In another embodiment, the first trench dielectric 14, the second trench dielectric 14-2 and the gate dielectric layer 16 may adopt the same dielectric material such as silicon dioxide. The trench conductive material 15 is connected to outside of the LDMOS device 100 through a dummy contact material, and finally electrically connected to the source metal contact 19. In an embodiment, the trench conductive material 15 and the gate conductive layer 17 adopt the same conductive material, e.g., polysilicon.

In the exemplary embodiment of FIG. 2, the trench conductive material 15 is operated as the resistor Rsn of the snubber illustrated in FIG. 1, and the first trench dielectric 14, the trench conductive material 15 and the N-type well region 102 are served as the capacitor Csn of the snubber illustrated in FIG. 1. The capacitance Cₒₓ per unit length of the capacitor Csn is relative to the depth difference La of the depth of the dummy trench and the depth of the P-type body region 104, and the width Lb of the dummy trench. The detailed equation is illustrated below:

$${C}_{ox} = \frac{{ɛ}_{o} \times {ɛ}_{sio 2}}{{t}_{ox}} \times W$$

Wherein εₒ is representative of the dielectric constant of air; εₛᵢₒ₂ representative of the dielectric constant of the first trench dielectric 14; tₒₓ is representative of the thickness of the first trench dielectric 14; and W equal to 2×La+Lb is representative of an effective width of the first trench dielectric 14. For example, when the thickness tₒₓ of the first trench dielectric 14 is set a value of 325 Åm, and the effective width W of the first trench dielectric 14 is set a value of 4.8 μm, the capacitance Cₒₓ per unit length of the capacitor Csn is equal to 5.01 nF/m.

In the exemplary embodiment of FIG. 2, the resistance of the resistor Rsn can be regulated by changing the depth of the dummy trench, the width b of the dummy trench 106 and the thickness toₓ of the first trench dielectric 14 in accordance with different requirements.

The operation of the LDMOS device 100 is similar to a traditional LDMOS. In detail, when a voltage signal larger than a threshold voltage is applied on the gate conductive layer 17, a conductive channel is formed along the interface of the gate dielectric layer 16 and the P-type body region 104. Electron current is allowed to flow from the N-type source region 11 through the P-type body region 104 to the light doped N− drift region 103, and continues flowing to the N-type drain region 13, i.e., the LDMOS 100 is switched on. In an embodiment, the LDMOS device 100 comprises a low side switch (e.g., the low side switches LS1, LS2 . . . , LSn of the DC/DC converter 50) of which the source electrode S is electrically connected to the logic ground.

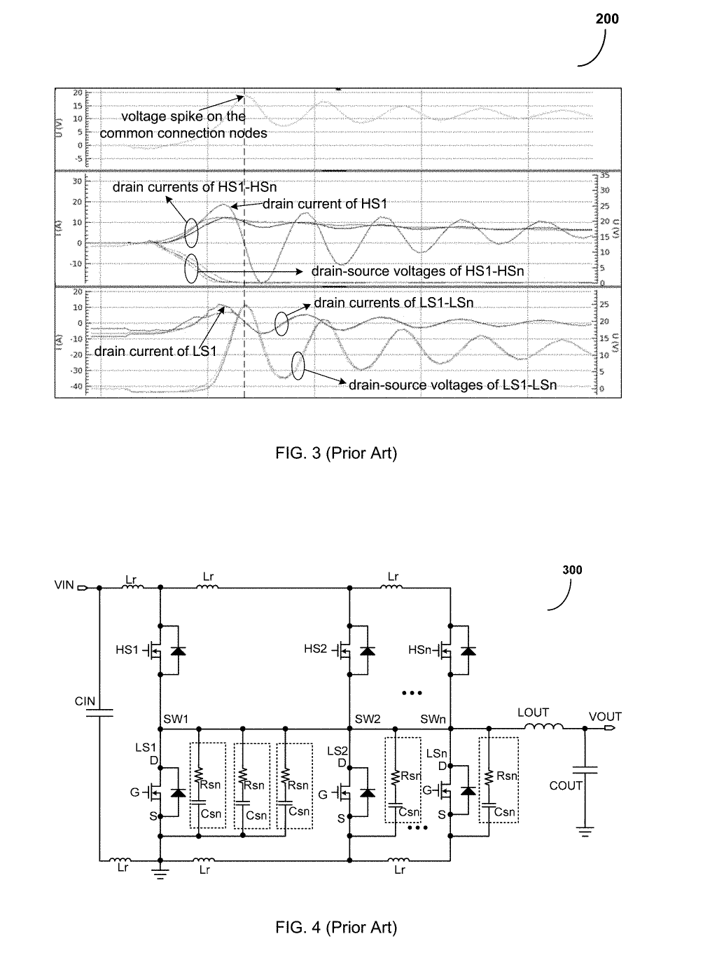

As mentioned in the DC-DC converter 50 of the BACKGROUND section, the parasitic inductance Lr of each resonance loop constituted in the DC-DC converter 50 is different. Thus, the voltage spikes generated on each of the common connection nodes (SW1, SW2, . . . , SWn) are different. FIG. 3 illustrates simulation waveforms 200 of the DC-DC converter 50. As shown in FIG. 3, voltage spikes generated on the node SW1, i.e., the common connection of the first high side MOS cell HS1 and the low side MOS cell LS1, is the largest. Therefore, large snubber is desired to be connected between the node SW1 and the logic ground to absorb the large voltage spikes.

FIG. 4 schematically illustrates a DC-DC converter 300 having a plurality of snubbers connected between the node SW1 and the logic ground. As shown in FIG. 4, three snubbers are illustrated to connect between the node SW1 and the logic ground to absorb the large voltage spike. As can be appreciated, the quantity of the snubbers is chosen to support the desired absorbing ability, and other suitable quantity of snubbers can be adopted to substitute for the person skilled in this art according to the different voltage of the spikes. For example, the larger the voltages of spikes, the more snubbers need to be connected.

FIG. 5 illustrates a cross-sectional view of a LDMOS device 400 according to an embodiment of the present invention. The LDMOS device 400 can be available for such as the DC-DC converter 300 in which more snubbers need to be connected between the node SW1 and the logic ground. Comparing to the LDMOS device 100, the LDMOS device 400 further comprises a plurality of dummy trench structures 107 formed in a termination region of the LDMOS device 400. The plurality of dummy trench structures 107 may vertically extend from the top surface of the termination region of the LDMOS 400 through the P-type body region 104 into the N-type well region 102. In an embodiment, the plurality of dummy trench structures 107 constituted in the termination region and the dummy trench structure 106 constituted in the main cell region of the LDMOS device 400 have the same structure. In an embodiment, the dummy trench structures 106 and 107 are formed at the same process step. The trench conductive materials 15 of the dummy trench structures 107 are also connected to outside of the LDMOS device 100 through dummy contact materials, and finally electrically connected to the source metal contact 19.

FIGS. 6-10 illustrate cross-sectional views illustrating a method of fabricating the LDMOS device 400 according to an embodiment of the present invention. As can be appreciated, process steps not necessary to the understanding of the invention have been omitted with the purpose of clarity.

In FIG. 6, the P-type semiconductor substrate 101 is provided, and the N-type well region 102 is formed in the P-type semiconductor substrate 101 through a well mask 70. In an embodiment, N-type Dopants are implanted into the semiconductor substrate 101 to form the N-type well region 102. In an embodiment, the semiconductor substrate 101 comprises a silicon substrate.

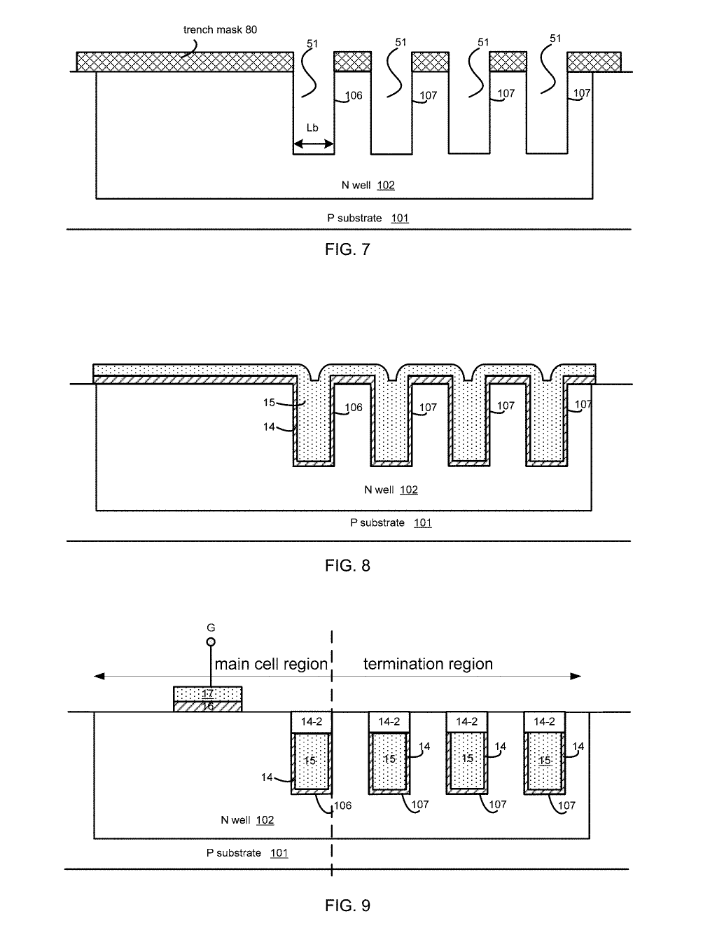

In FIG. 7, dummy trenches 51 are formed in the N-type well region 102 by etching the N-type well region 102 through a trench mask 80. In an embodiment, a photoresist layer is patterned to form trench window on the N-type well region 102, so that a portion of the N-type well region 102 could be removed to form dummy trenches 51. In an embodiment, the dummy trenches 51 are formed by reactive ion etching. In an embodiment, the dummy trenches 51 may have a depth in the range of 500 nm to 2 μm.

In FIG. 8, the mask 80 is removed, and the first trench dielectric 14 and the trench conductive material 15 are formed in the dummy trenches 51. At first, the first trench dielectrics 14 are grown both on the bottom and sidewalls of the dummy trenches 51. Before the first trench dielectrics 14 formation, the surface quality of the dummy trenches 51 may be improved by sacrificial oxidation and oxide etching. The first trench dielectrics 14 may comprise one or more suitable dielectric materials. In an embodiment, thermal oxides are grown on the surface of the dummy trenches 51. The thickness of the first trench dielectric 14 is chosen to support the desired capacitance of the capacitor Csn of the snubber. For example, the first trench dielectric 14 with a thickness in the range of 150 Åm to 450 Åm may be used.

Following formation of the first trench dielectric 14, the trench conductive material 15 is then deposited in each of the dummy trenches 51 to form the dummy trench structures. The trench conductive material 15 may comprise any conductive material, such as doped polysilicon, a silicide, or metal.

In FIG. 9, the excess first trench dielectric 14 and the excess trench conductive material 15 on the surface of the N-type well region 102 and in the dummy trenches 51 are removed such that the surface is planarized. This may be accomplished, for example, by etchback or chemical mechanical planarization (CMP). In an embodiment, the dummy trench 51 is completely filled with the trench conductive material 15, and an IDL (e.g., the IDL 105 illustrated in FIG. 5) is formed on the trench conductive material 15 for insulating the trench conductive material 15 from the source metal contact 19. In another embodiment, the filling height Lc of the trench conductive material 15 is smaller than the height Ld of the dummy trench 51, and the top surface of the trench conductive material 15 is lower than the top surface of the of the dummy trench 51, and the second trench dielectric 14-2 is adopted to form on the trench conductive material 15 and the dummy trenches 51 is completely filled after the second trench dielectric 14-2 is formed.

Afterward, the gate region is formed on the top surface of the N-type well region 102 of the main cell region. In detail, the gate dielectric layer 16 is grown or deposited on the top surface of the N-type well region 102, and then the gate conductive layer 17 is formed on the gate dielectric layer 16. The gate conductive layer 17 is electrically connected to outside of the LDMOS device 400 through the gate metal contact that serves as a gate electrode G.

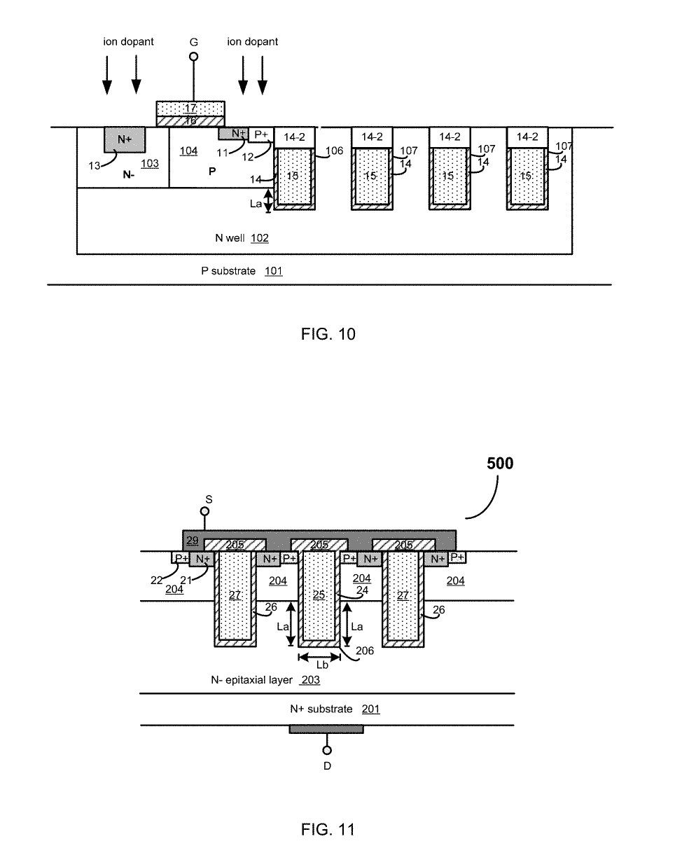

In FIG. 10, the light doped N− drift region 103, the P-type body region 104, the N-type source region 11, the heavy doped P+ body contact region 12 and the N-type drain region 13 are formed in the main cell region of the N-type well region 102. In an embodiment, dopants are respectively implanted into the main cell region of the N-type well region 102 by a gate self-aligned process. In such a process, a gate seal oxide needs to be formed at the sidewalls and top surface of the gate region so as to insulate the gate conductive layer 17 from the N-type source region 11. In another embodiment, masks are adopted to implant ions. In this process, masks are formed on the top surface of the N-type well region 102. The masks respectively define areas of the light doped N− drift region 103, the P-type body region 104, the N-type source region 11, the heavy doped P+ body contact region 12 and the N-type drain region 13. In an embodiment, prior to the masks formation, an oxide layer as a protection layer is grown on the N-type well region 102. The masks may comprise a photoresist material formed by lithography. Then, the light doped N− drift region 103, the P-type body region 104, the N-type source region 11, the heavy doped P+ body contact region 12 and the N-type drain region 13 are formed by ion-implantations. Then, the masks are removed and the IDL 105 is formed on the top surface of the N-type well region 102. When masks are adopted for ion implantation, the filling height of the trench conductive material 15 can be equal to the depth of the dummy trench since the trench conductive material 15 can be insulated from the N-type source region 11 by the IDL 105. The IDL 105 may comprise any suitable dielectric material, such as silicon nitride or silicon dioxide. One or more metallization layers (e.g., aluminum, copper, silicide, or the like) are deposited and patterned to form the source metal contact 19 and the drain metal contact 18. In an embodiment, a passivation layer (not shown) may be deposited and patterned to protect the top metallization layer. The trench conductive materials 15 of the dummy trench structures 106 and 107 are connected to outside of the LDMOS device 400 through dummy contact materials, and finally electrically connected to the source metal contact 19.

FIG. 11 illustrates a cross-sectional view of a Verticality Diffused Metal Oxide Semiconductor (VDMOS) device 500 according to an embodiment of the present invention. As shown in FIG. 11, the VDMOS device 500 comprises a semiconductor substrate 201 of a heavy doped first conductivity type, an epitaxial layer 203 of the light doped first conductivity type, a source region 21 of the first conductivity type, a trench gate region, and a body region 204 of a second conductivity type opposite to the first conductivity type. The semiconductor substrate 201 can also be served as a drain region of the VDMOS device 500. In an embodiment, the semiconductor substrate 201 comprises a silicon substrate. In the following description, the first conductivity type is assumed to be N-type conductivity, and the second conductivity type is assumed to be P-type conductivity. However, one with ordinary skills in the art should note that in other embodiments, the N-type conductivity and the P-type conductivity may also be applied alternatively for the first conductivity type and the second conductivity type.

Specifically, the light doped N− epitaxial layer 203 is grown on the heavy doped N+ semiconductor substrate 201. In an embodiment, the light doped N− epitaxial layer 203 may be grown by vapor phase epitaxy. The P-type body region 204 is formed in the top of the N− epitaxial layer 203. The N-type source region 21 and the heavy doped P+ body contact region 22 are formed in the P-type body region 204. A source metal contact 29 served as a source electrode S contacting the N-type source region 21 and the heavy doped P+ body contact region 22 through vias is formed on the top of the light doped N− epitaxial layer, and electrically connected to outside of the VDMOS device 500.

The trench gate region formed in a gate trench. The trench gate region comprises a gate dielectric 26 and a gate conductive material 27. The gate dielectric 26 comprising an insulating material, such as silicon dioxide, is grown both on the bottom and sidewalls of the gate trench. The gate conductive material 27 is formed on the gate dielectric 26. The gate dielectric 26 vertically separates the gate conductive material 27 from a drift region, which in this example comprises the portion of the light doped N− epitaxial layer 203 between the top of the heavy doped N+ substrate 201 and the bottom of P-type body region 204.

Moreover, the VDMOS device 500 further comprises a dummy trench structure 206 vertically extending into the drift region from the top surface of the light doped N− epitaxial layer 203. The dummy trench structure 206 comprises a dummy trench, a trench dielectric 24 and a trench conductive material 25. The trench dielectric 24 comprising an insulating material is grown both on the bottom and sidewalls of the dummy trench. The trench conductive material 25 is formed on the trench dielectric 24. The trench dielectric 24 vertically insulates the trench conductive material 25 from the P-type body region 204 and the drift region. In an embodiment, the trench conductive material 25 and the gate conductive material 27 can adopt the same material. An IDL 205 is deposited on the top surface of the light doped N− epitaxial layer 203 so as to separate the trench conductive material 25 and the gate conductive material 27 from the source metal contact 29. In an embodiment, the trench dielectric 24 and the IDL 205 can adopt the same material, such as silicon dioxide. In an embodiment, the depth of the dummy trench is greater than the depth of the P-type body region 204, and the depth difference of the depth of the dummy trench and the depth of the P-type body region 204 is labeled as La, and the width of the dummy trench is labeled as Lb. In an embodiment, the dummy trench structure 206 and the trench gate region have the same structure which can be formed in the same process steps. The trench conductive material 25 is connected to outside of the VDMOS device 500 through a dummy contact material, and finally electrically connected to the source metal contact 29.

In the exemplary embodiment of FIG. 11, the trench conductive material 25 is operated as the resistor Rsn of the snubber of FIG. 1, and the trench dielectric 24, the trench conductive material 25 and the drift region are served as the capacitor Csn of the snubber of FIG. 1. The capacitance Cₒₓ per unit length of the capacitor Csn is relative to the effective width W of the trench dielectric 24. The detailed equation is the same as that mentioned in the embodiment of FIG. 2.

In the exemplary embodiment of FIG. 11, the resistance of the resistor Rsn can be regulated by changing the depth and width of the dummy trench 206, and the thickness of the trench dielectric 24 in accordance with different requirements. In an embodiment, the VDMOS device 500 comprises a low side switch (e.g., the low side switches LS1, LS2 . . . , LSn of the DC/DC converter 50) of which the source electrode S is electrically connected to the logic ground.

As can be appreciated, the conductivity and doping of the material/regions disclosed herein may be varied, with appropriate changes to the conductivity of other materials/regions in accordance with different applications. For example, when the semiconductor substrate 201 is P-type semiconductor substrate, the source regions 21 are P+ source regions, the body regions are N-type body regions.

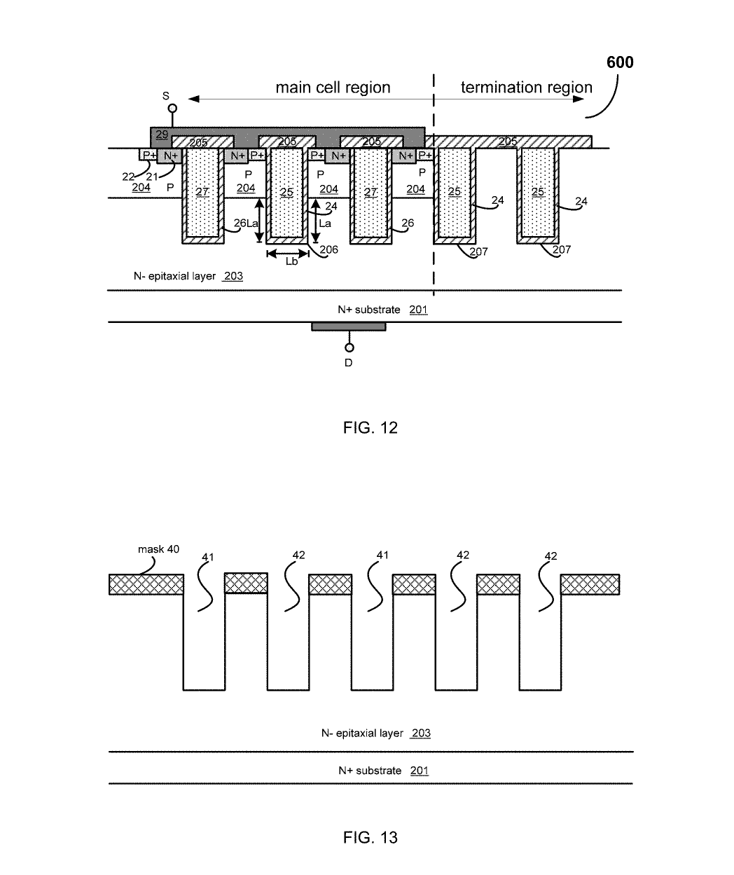

FIG. 12 illustrates a cross-sectional view of a Verticality Diffused Metal Oxide Semiconductor (VDMOS) device 600 according to an embodiment of the present invention. Comparing to the VDMOS device 500, the VDMOS device 600 further comprises a plurality of dummy trench structures 207 constituted in the termination region of the VDMOS device 600. The plurality of dummy trench structures 207 vertically extend from the top surface of the VDMOS device 600 into the light doped N− epitaxial layer 203. In an embodiment, the plurality of dummy trenches structures 207 constituted in the termination region of the VDMOS device 600 and the dummy trench structure 206 constituted in the main cell region of the VDMOS device 600 have the same structure. In an embodiment, the dummy trench structures 206 and 207 are formed at the same process steps. The trench conductive materials 25 are also connected to outside of the VDMOS device 600 through dummy contact materials, and finally electrically connected to the source metal contact 29.

FIGS. 13-15 illustrate cross-sectional views illustrating a method of fabricating the VDMOS device 600 according to an embodiment of the present invention. As can be appreciated, process steps not necessary to the understanding of the invention have been omitted in the interest of clarity.

In FIG. 13, the light doped N− epitaxial layer 203 is grown on the heavy doped N+ semiconductor substrate 201. In an embodiment, the heavy doped N+ semiconductor substrate 201 comprises a silicon substrate, and the light doped N− epitaxial layer 203 may be grown by vapor phase epitaxy. The thickness and doping profile of the light doped N− epitaxial layer 203 are chosen to provide the drift region with the desired off state characteristics (e.g., breakdown voltage). For example, a device with a breakdown voltage of 100V may have a thickness of the light doped N− epitaxial layer 203 in the range of 5 μm to 15 μm and a doping profile with a concentration in the range of 5×1016 cm-3 to 5×1017 cm-3 near the heavy doped N+ substrate 201, a concentration in the range of 5×1015 cm-3 to 5×1016 cm-3 near the bottom of the P-type body region 204, and a concentration in the range of 5×1016 cm-3 to 5×1017 cm-3 at a top surface of the light doped N− epitaxial layer 203. In an embodiment, the doping concentration of the light doped N− epitaxial layer 203 decreases in a substantially linear fashion with vertical position between the top of heavy doped N+ substrate 201 and the bottom of the P-type body region 204, then remains substantially constant with vertical position from the bottom of the P-type body region 204 to the top surface of the light doped N− epitaxial layer 203.

Gate trenches 41 and dummy trenches 42 are formed by etching the light doped N− epitaxial layer 203 through a mask 40. In an embodiment, the gate trenches 41 and the dummy trenches 42 are formed by reactive ion etching. The depth of the gate trenches 41 and the depth of the dummy trenches 42 are chosen to be greater than the depth of the subsequently formed P-type body region 204. By way of example, the gate trenches 41 and the dummy trenches 42 may have a depth in the range of 0.5 μm to 2 μm.

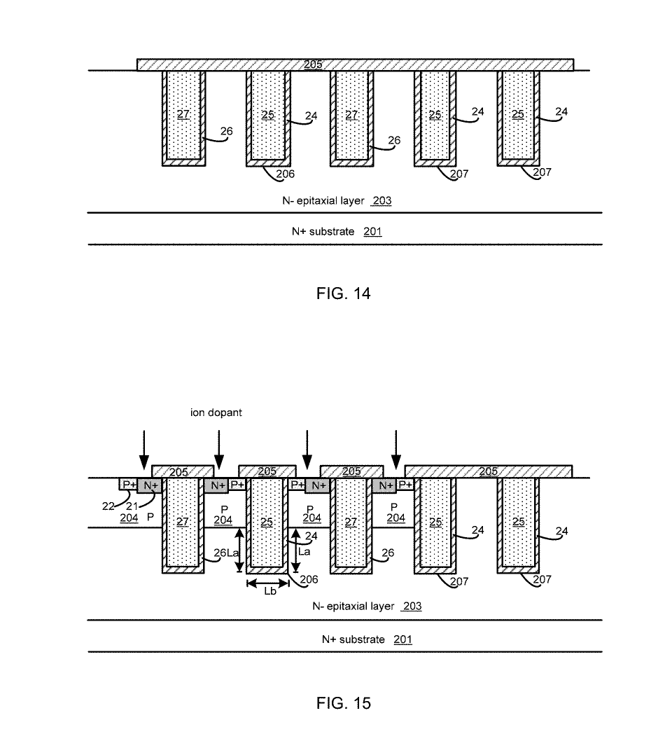

In FIG. 14, the mask 40 is removed, and the trench dielectrics 24 and the gate dielectrics 26 are respectively formed in the gate trenches 41 and the dummy trenches 42. Before the trench dielectrics 24 and the gate dielectrics 26 formation, the surface quality of the gate trenches 41 and the dummy trenches 42 may be improved by sacrificial oxidation and oxide etching. The trench dielectrics 24 and the gate dielectrics 26 may be adopted the same material that comprises the same one or more suitable dielectric materials. In an embodiment, thermal oxides are grown on the surface of the gate trenches 41 and the dummy trenches 42. The thickness of the gate dielectrics 26 are chosen to support the desired gate-to-source operating voltage, and the thickness of the trench dielectrics 24 is chosen to support the desired capacitance of the capacitor Csn of the snubber. In an embodiment, the trench dielectrics 24 with a thickness in the range of 150 Åm to 450 Åm may be used.

Following the formation of the trench dielectrics 24 and the gate dielectrics 26, the trench conductive materials 25 and the gate conductive materials 27 are respectively deposited in each of the dummy trenches 42 and the gate trenches 41 to form the dummy trench structures and the trench gate regions. The trench conductive materials 25 and the gate conductive materials 27 may be formed in the same process step adopting the same material, such as doped polysilicon, a silicide, or metal. The gate trenches 41 and the dummy trenches 42 are completely filled and then the excess trench conductive materials 25 and the gate conductive materials 27 on the surface of the light doped N− epitaxial layer 203 are removed such that the surface is substantially planarized. This may be accomplished, for example, by etchback or CMP.

Following the formation of the trench gate regions and the dummy trench structures 206 and 207, the IDL 205 is deposited and patterned on the top surface of the light doped N− epitaxial layer 203 to insulate the trench conductive material 25 and the gate conductive material 27 from the source metal contact 29. The IDL 205 can adopt the any suitable dielectric material, such as silicon dioxide.

In FIG. 15, the P-type body region 204, the N-type source region 21 and the heavy doped P+ body contact region 22 are formed in the main cell region of the VDMOS device 600 by masking and ion-implantation techniques. One or more metallization layers (e.g., aluminum, copper, silicide, or the like) are deposited and patterned to form the source metal contact 29 (as illustrated in FIG. 12) which is served as a source electrode S of the VDMOS device 600. The heavy doped N+ substrate 201 may be thinned from the backside and then a metallization layer deposited on the back of the heavy doped N+ substrate 201 to form a drain electrode D of the VDMOS device 600. A passivation layer (not shown) may be deposited and patterned to protect the top metallization layer.

In the above description, doped types, dose and others parameters of the impurity may not be described, which can be chosen by the ordinary person skilled in this art to support the desired applications. While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

I/We claim:

1. A main cell region of a Laterally Diffused Metal Oxide Semiconductor (LDMOS) device, the main cell region comprising:
a semiconductor initial layer of a first conductivity type;
a drain region of the first conductivity type formed in the semiconductor initial layer;
a body region of a second conductivity type opposite to the first conductivity type, formed adjacent to the drain region in the semiconductor initial layer;
a gate region, formed on the body region;
a source region of the first conductivity type formed in the body region, wherein the source region is at one side of the gate region, and the drain region is at the other side of the gate region; and
a first dummy trench structure, vertically extending from the top surface of the semiconductor initial layer through the body region into the semiconductor initial layer, wherein the body region separates the first dummy trench structure from the source region.

2. The main cell region of the LDMOS device of claim 1, wherein the first dummy trench structure further comprises:
a dummy trench, vertically extending from the top surface of the semiconductor initial layer through the body region into the semiconductor initial layer;
a first trench dielectric formed on the bottom and sidewalls of the dummy trench; and
a trench conductive material filling in the dummy trench, wherein the first trench dielectric insulates the trench conductive material from the semiconductor initial layer.

3. The main cell region of the LDMOS device of claim 2, wherein the top surface of the trench conductive material is lower than the bottom of the source region.

4. The main cell region of the LDMOS device of claim 2, wherein the first dummy trench structure further comprises a second trench dielectric formed on the trench conductive material, and wherein the dummy trench is completely filled after the second trench dielectric is formed.

5. The main cell region of the LDMOS device of claim 1, further comprising a body contact region of the second conductivity type formed in the body region between the first dummy trench structure and the source region, and wherein the body contact region separates the first dummy trench structure from the source region.

6. The main cell region of the LDMOS device of claim 1, wherein the LDMOS device further comprises a termination region located in the periphery of the main cell region, and wherein the termination region comprises a second dummy trench structure vertically extending from the top surface of the semiconductor initial layer into the semiconductor initial layer, and wherein the first dummy trench structure and the second dummy trench structure have the same structure.

7. The main cell region of the LDMOS device of claim 6, wherein the trench conductive material is connected to outside of the LDMOS device through a contact material contacting the trench conductive material, and electrically connected to a source contact metal contacting the source region.

8. A main cell region of a Verticality Diffused Metal Oxide Semiconductor (VDMOS) device, comprising:
a semiconductor substrate of a first conductivity type, served as a drain region;
an epitaxial layer of the first conductivity type formed on the semiconductor substrate;
a body region of a second conductivity type opposite to the first conductivity type formed in the top of the epitaxial layer;
a source region of the first conductivity type formed in the body region;
a trench gate region, vertically extending from the top surface of the epitaxial layer through the body region into the epitaxial layer; and
a first dummy trench structure, vertically extending from the top surface of the epitaxial layer through the body region into the epitaxial layer, wherein the body region separates the first dummy trench structure from the source region.

9. The main cell region of the VDMOS device of claim 8, wherein the first dummy trench structure further comprises:
a dummy trench, vertically extending from the top surface of the semiconductor substrate through the body region into the epitaxial layer;
a first trench dielectric formed on the bottom and sidewalls of the dummy trench; and
a trench conductive material formed on the first trench dielectric in the dummy trench.

10. The main cell region of the VDMOS device of claim 9, further comprising an interlayer dielectric layer formed on the top surface of the epitaxial layer, wherein the interlayer dielectric layer insulates the trench conductive material from a source contact metal contacting the source region.

11. The main cell region of the VDMOS device of claim 9, further comprising a body contact region of the second conductivity type formed in the body region between the first dummy trench structure and the source region, wherein the body contact region separates the first dummy trench structure from the source region.

12. The main cell region of the VDMOS device of claim 9, wherein the VDMOS device further comprises a termination region located in the periphery of the main cell region, and wherein the termination region comprises a second dummy trench structure vertically extending from the top surface of the epitaxial layer into the epitaxial layer, and wherein the first dummy trench structure and the second dummy trench structure have the same structure.

13. A method of fabrication a LDMOS device, comprising forming a main cell region, wherein forming the main cell region comprises:
forming a semiconductor initial layer of a first conductivity type;
forming a first dummy trench structure in the semiconductor initial layer;
forming a body region of a second conductivity type opposite to the first conductivity type in the semiconductor initial layer, wherein the first dummy trench structure vertically extends from the top surface of the semiconductor initial layer through the body region into the semiconductor initial layer;
forming a gate region on the body region;
forming a drain region of the first conductivity type adjacent to the body region in the semiconductor initial layer; and
forming a source region of the first conductivity type in the body region, wherein the source region is at one side of the gate region, and the drain region is at the other side of the gate region, and wherein the body region separates the first dummy trench structure from the source region.

14. The method of claim 13, wherein forming the first dummy trench structure in the semiconductor initial layer comprises:
forming a dummy trench vertically extending from the top surface of the semiconductor initial layer through the body region into the semiconductor initial layer;
forming a first trench dielectric both on the bottom and sidewalls of the dummy trench; and
filling the dummy trench with a trench conductive material on the first trench dielectric, wherein the first trench dielectric insulates the trench conductive material from the semiconductor initial layer.

15. The method of claim 14, wherein forming a first dummy trench structure in the semiconductor initial layer further comprises forming a second trench conductive material on the trench conductive material, and wherein the dummy trench is completely filled after the second trench dielectric is formed.

16. The method of claim 13, further comprising forming a termination region, and wherein forming the termination region comprises:
forming a second dummy trench structure vertically extending from the top surface of the semiconductor initial layer into the semiconductor initial layer, and wherein the first dummy trench structure and the second dummy trench structure have the same structure.

17. A method of fabrication a VDMOS device, comprising forming a main cell region, wherein forming the main cell region comprises:
providing a semiconductor substrate of a first conductivity type, served as a drain region;
forming an epitaxial layer of the first conductivity type on the semiconductor substrate;
forming a first dummy trench structure and a trench gate region in the epitaxial layer;
forming a body region of a second conductivity type opposite to the first conductivity type in the epitaxial layer, wherein the first dummy trench structure and the trench gate region vertically extend from the top surface of the epitaxial layer through the body region into the epitaxial layer; and
forming a source region of the first conductivity type in the body region, wherein the body region separates the first dummy trench structure from the source region.

18. The method of claim 17, wherein forming the first dummy trench structure and the trench gate region in the epitaxial layer comprises:
forming trenches vertically extending from the top surface of the epitaxial layer through the body region into the epitaxial layer;
forming trench dielectrics both on the bottom and sidewalls of the trenches; and
filling the trenches with trench conductive materials on the trench dielectrics.

19. The method of claim 17, wherein forming the main cell region further comprises forming an interlayer dielectric layer on the top surface of the epitaxial layer, and wherein the interlayer dielectric layer insulates the trench conductive material from a source contact metal contacting the source region.

20. The method of claim 17, further comprising forming a termination region, and wherein forming the termination region comprises:
forming a second dummy trench structure vertically extending from the top surface of the epitaxial layer into the epitaxial layer, and wherein the first dummy trench structure and the second dummy trench structure have the same structure.
